(19) United States
(12) Patent Application Publication
(10) Pub. No.: US 2014/0336968 A1
(43) Pub. Date: Nov. 13, 2014

(54) METHOD AND APPARATUS FOR CALIBRATING A MAGNETIC SENSOR

(71) Applicant: STMICROELECTRONICS (CHINA) INVESTMENT CO. LTD, Shanghai (CN)

(72) Inventors: Travis Tu, Shanghai (CN); Shu Fang, Shanghai (CN)

(73) Assignee: STMICROELECTRONICS (CHINA) INVESTMENT CO. LTD, Shanghai (CN)

(21) Appl. No.: 14/271,982

(22) Filed: May 7, 2014

(30) Foreign Application Priority Data
May 8, 2013 (CN) 201310172424.1

(51) Int. Cl. G01R 35/00

(52) U.S. Cl. CPC G01R 35/007
USPC 702/87

(57) ABSTRACT

A magnetic sensor is calibrated by acquiring magnetic field measurements, fitting at least part of the plurality of magnetic field measurements to an ellipsoid model to obtain a coordinate of a center of the ellipsoid model, and determining a calibration offset according to the coordinate of the center of the ellipsoid model. The calibration offset is used to calibrate the magnetic sensor. The magnetic sensor itself obtains the magnetic field measurements. A processing device coupled to the magnetic sensor operates to process the magnetic field measurements is accordance with the ellipsoid mode and determine the calibration offset.

### PRIORITY CLAIM

This application claims priority from Chinese Application for Patent No. 201310172424.1 filed May 8, 2013, the disclosure of which is incorporated by reference.

### TECHNICAL FIELD

This invention relates generally to measurement technology, and more particularly to a method and apparatus for calibrating a magnetic sensor.

### BACKGROUND

Magnetic sensors are popular components used in electronic devices. A magnetic sensor operates to measure geomagnetic fields with the measurement results used by electronic devices for navigation, gaming, and other orientation related applications. However, magnetic sensors may be disturbed by soft iron and hard iron interferences. Hard iron interference may be caused by objects that produce magnetic fields, for example, a speaker, a motor, or a piece of magnetized iron. Soft iron interference may be caused by sources inside and/or outside casing of the electronic devices which contain a magnetic sensor, for example metal frames, circuits or shielding with metal such as Fe/Ni/Gu.

Currently, there are several traditional ways to calibrate a magnetic sensor. As illustrate in FIG. 1, calibration using a golden sample is one of the traditional methods. A golden sample may be an ideal calibrated magnetic sensor same as the one to be calibrated. A magnetic measurement represented by vector A is obtained using the magnetic sensor to be calibrated, and a magnetic measurement represented by vector B measured at the same place and same orientation is obtained using the golden sample device. The magnetic interference is calculated as the offset between vectors A and B, i.e. O=A-B. However, a golden sample is very hard to find and the geomagnetic field may change along with time and environment.

Another traditional way to calibrate a magnetic sensor is a horizontal plane rotation method. In this method, the device containing a magnetic sensor is placed on a horizontal desktop and rotated for a plurality of times. FIG. 2A is a 3D plot of magnetic measurements obtained on the horizontal plane. The hard iron offset (Oₛ, O_{y}) on the X axis and Y axis is calculated as follows:

(X−O_{X})²+(Y−O_{Y})²=R² (1)

wherein R is the radius of the circle in FIG. 2A. The hard iron offset O_{Z} on the vertical Z axis is calculated as follows:

O_{Z}=(Oᵤₚ+O_{down})/2 (2)

wherein Oᵤₚ and O_{down} are magnetic measurements obtained when the magnetic sensor faces up and down respectively.

However, most horizontal planes are sustained by a metal holder which can generate additional magnetic interference to the output of the magnetic sensor. Such additional interference can cause asymmetric distortion at different directions, and the plot of the measurements obtained may be illustrated as in FIG. 2B. Such additional interference may increase the error possibility of the calibration.

Another traditional method to calibrate a magnetic sensor is to obtain magnetic measurements at various directions and use a sphere model as illustrated in FIG. 3 to calculate the offset. However, due to the soft iron interference, a sphere model is not accurate.

A further method to calibrate a magnetic sensor is to put it in a Helmholtz cage to cancel the geomagnetic field at the position, and therefore the magnetic measurement obtained is the offset needed for calibration. However, such cages are quite expensive and time consuming when used. Therefore, it is not a practical way to calibrate a magnetic sensor included in consumer electronics.

### SUMMARY

Due to the above stated problems, a method and an apparatus for a magnetic sensor, in particular, to eliminate hard iron interferences is desired. Such a method and apparatus should be easy to use, with less complexity to implement, and should also take not only hard iron interference but also soft iron interference into consideration.

In an embodiment, a method for calibrating a magnetic sensor comprises: acquiring a plurality of magnetic field measurements; fitting at least part of the plurality of magnetic field measurements to an ellipsoid model to obtain a coordinate of a center of the ellipsoid model; determining a calibration offset according to the coordinate of the center of the ellipsoid model; and calibrating the magnetic sensor using the calibration offset.

Said step of fitting comprises determining an expression of the ellipsoid model containing a plurality of ellipsoid parameters; substituting at least part of the plurality of magnetic field measurements into the expression of the ellipsoid model to obtain a matrix equation including a matrix of the magnetic field measurements and a matrix of the plurality of ellipsoid parameters; solving the matrix equation using Gaussian principle elimination to obtain the plurality of ellipsoid parameters; and determining the coordinate of the center of the ellipsoid model using the plurality of ellipsoid parameters.

Said step of solving comprises traversing the matrix of the magnetic field measurements to determine principles thereof; converting the matrix of the magnetic field measurements into a triangular matrix based on the principles obtained; and solving the matrix equation based on the triangular matrix to obtain the ellipsoid parameters.

The expression of the ellipsoid model is defined by:

a₁x²+a₂y²+a₃z²+a₄xy+a₅xz+a₆yz+a₇x+a₈y+a₉z=1

wherein (x, y, z) represents a point located on the ellipsoid model, and a₁-a₉ represent the ellipsoid parameters, and the coordinate of the center of the ellipsoid model is defined by (x₀, y₀, z₀), wherein x₀, y₀ and z₀ satisfy the following relationship:

$${x}_{0} = - \frac{{a}_{4}}{2 {a}_{1}} {y}_{0} - \frac{{a}_{5}}{2 {a}_{1}} {z}_{0} - \frac{{a}_{7}}{2 {a}_{1}}$$

$${y}_{0} = - \frac{2 {a}_{1} {a}_{6} - {a}_{4} {a}_{5}}{4 {a}_{1} {a}_{2} - {a}_{4}^{2}} {z}_{0} - \frac{2 {a}_{1} {a}_{8} - {a}_{4} {a}_{7}}{4 {a}_{1} {a}_{2} - {a}_{4}^{2}}$$

$${z}_{0} = - \frac{\begin{matrix}( 2 {a}_{1} {a}_{9} - {a}_{7} {a}_{5} ) ( 4 {a}_{1} {a}_{2} - {a}_{4}^{2} ) - \\ ( 2 {a}_{1} {a}_{6} - {a}_{4} {a}_{5} ) ( 2 {a}_{1} {a}_{8} - {a}_{4} {a}_{7} )\end{matrix}}{( 4 {a}_{1} {a}_{3} - {a}_{5}^{2} ) ( 4 {a}_{1} {a}_{2} - {a}_{4}^{2} ) - 2 {( {a}_{1} {a}_{6} - {a}_{4} {a}_{5} )}^{2}}$$

The plurality of magnetic field measurements comprise at least nine different magnetic field measurements.

Each of the plurality of magnetic field measurements is measured along three orthogonal axes.

The calibration offset is equal to a vector from a origin of the three orthogonal axes to the center of the ellipsoid model.

Said step of calibrating comprises subtracting the calibration offset from the magnetic field measurements.

In an embodiment, an apparatus configured to perform the steps of any of the methods above comprises: a magnetic sensor configured to obtain a plurality of magnetic field measurements; and a processing unit coupled with the magnetic sensor, configured to process the plurality of magnetic field measurements for calibration of the magnetic sensor.

The magnetic sensor is located in an electronic compass.

The method described herein does not require an additional device for calibration, for example no golden sample or Helmholtz cage is needed. Also, a more accurate model is adopted for calculation of the offset which may lead to more accurate calibration of the magnetic sensor. Also, the method and apparatus described herein offers a fast and efficient way for calibration.

The foregoing has outlined, rather broadly, features of the present disclosure. Additional features of the disclosure will be described, hereinafter, which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a traditional method for calibrating a magnetic sensor;

FIGS. 2A and 2B illustrate another traditional method for calibrating a magnetic sensor;

FIG. 3 is a 3D plot of a sphere model of magnetic field used in yet another traditional method for calibrating an magnetic sensor;

FIG. 4 is a 3D plot of a ellipsoid model of magnetic field;

FIG. 5 shows a flow chart of a method for calibrating a magnetic sensor according to an embodiment;

FIG. 6 shows a flow chart of Gaussian principal elimination used in the method in FIG. 5; and

FIG. 7 shows a block diagram of an apparatus according to an embodiment.

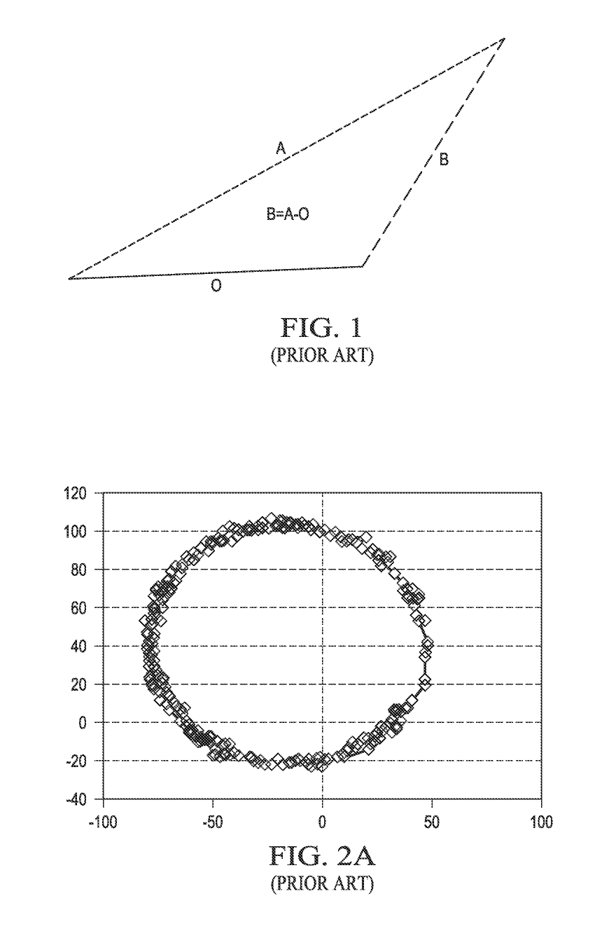

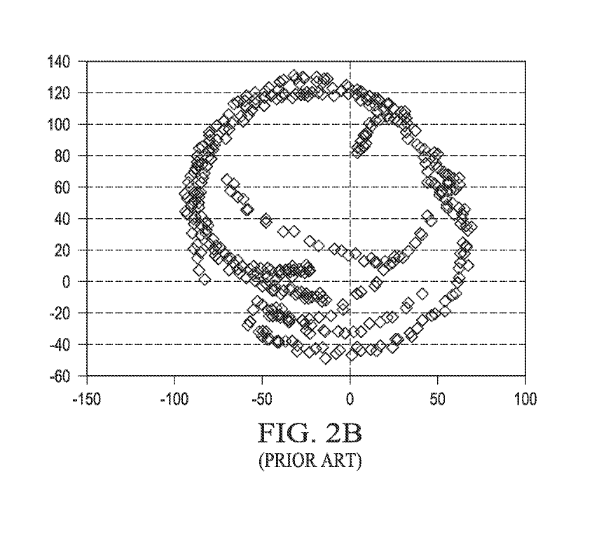

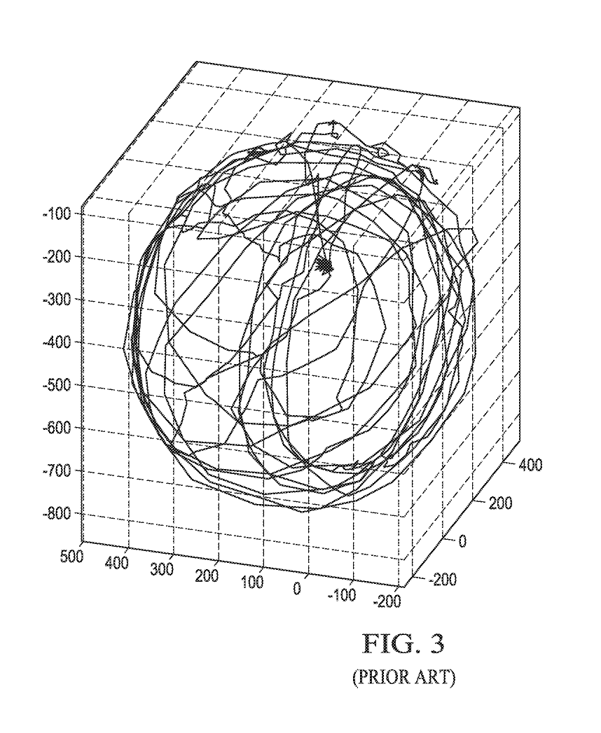

### DETAILED DESCRIPTION OF THE DRAWINGS

Corresponding numerals and symbols in different figures generally refer to corresponding parts unless otherwise indicated.

The making and using of embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention. It should also be appreciated that, the steps recorded in the method may be performed in a different order, and/or performed in parallel. Moreover, the methods herein may comprise additional steps and/or omit to perform one or more illustrated steps. The scope of the invention is not limited in such aspects.

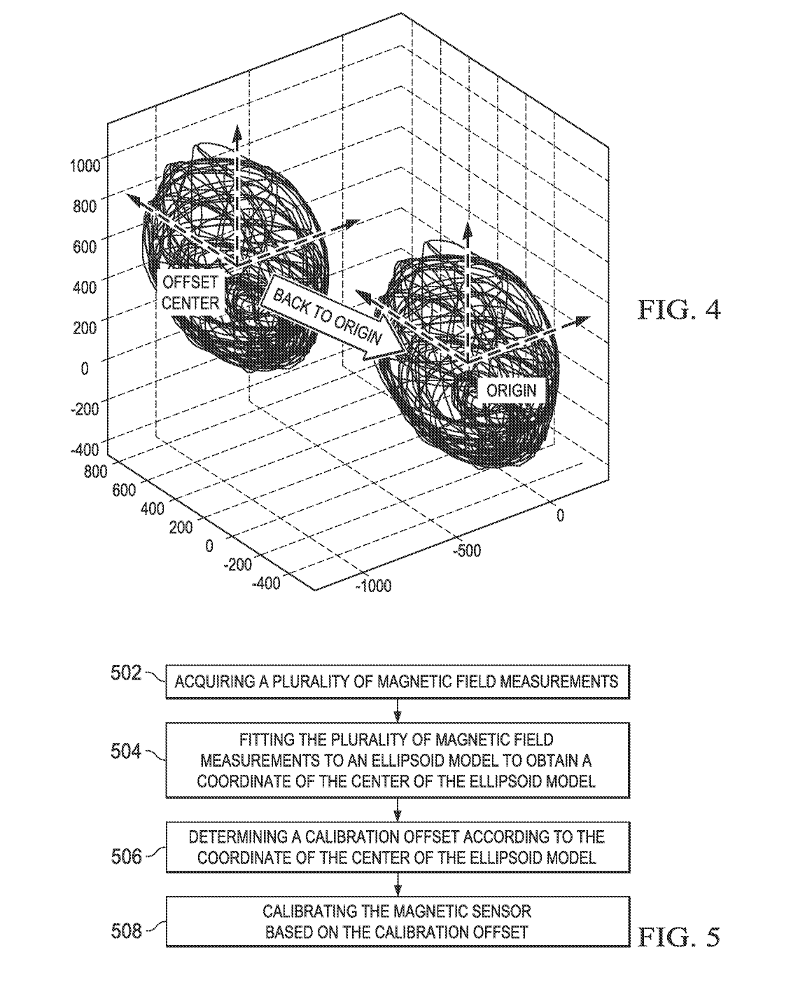

As stated in the background section, using a sphere model to calculate the offset caused by magnetic interferences is not accurate. In an embodiment, an ellipsoid is instead used considering the influence of soft iron interference. Also, hard iron interferences may cause a shift of the center of the ellipsoid. Therefore, calculation of an offset of the center of the ellipsoid is performed to cancel the influence of hard iron interference. FIG. 4 is a 3D plot of an ellipsoid model and illustrates the shift of the center of the ellipsoid.

FIG. 5 illustrates a method for calibrating a magnetic sensor. At block 502, a magnetic sensor is rotated at the same position for a plurality of times to obtain a plurality of magnetic field measurements. In one embodiment, the measurements may be in the form of coordinates along three orthogonal axes X, Y and Z.

At block 504, the plurality of magnetic field measurements are fitted to an ellipsoid model to obtain a coordinate of the center of the ellipsoid model. In one embodiment, an equation may be used to describe the ellipsoid model, for example the equation may be as follows:

a₁xᵢ²+a₂yᵢ²+a₃zᵢ²+a₄xᵢyᵢ+a₅xᵢzᵢ+a₆yᵢzᵢ+a₇xᵢ+a₈yᵢ+a₉zᵢ=1 (1)

wherein (xᵢ, yᵢ, zᵢ) is a coordinate of any point on the ellipsoid model, and a₁-a₉ are the ellipsoid parameters.

Theoretically, the coordinate of the center of the ellipsoid model should be (0, 0, 0). However, under the influence of hard iron interference, the center of the ellipsoid model may shift to a point with a coordinate as (x₀, y₀, z₀). In one embodiment, x₀, y₀ and z₀ may be expressed in terms of the ellipsoid parameters, for example by equations as follows:

$$\begin{matrix}{x}_{0} = - \frac{{a}_{4}}{2 {a}_{1}} {y}_{0} - \frac{{a}_{5}}{2 {a}_{1}} {z}_{0} - \frac{{a}_{7}}{2 {a}_{1}} & ( 2 ) \\ {y}_{0} = - \frac{2 {a}_{1} {a}_{5} - {a}_{4} {a}_{5}}{4 {a}_{1} {a}_{2} - {a}_{4}^{2}} {z}_{0} - \frac{2 {a}_{1} {a}_{8} - {a}_{4} {a}_{7}}{4 {a}_{1} {a}_{2} - {a}_{4}^{2}} & ( 3 ) \\ {z}_{0} = - \frac{\begin{matrix}( 2 {a}_{1} {a}_{9} - {a}_{7} {a}_{5} ) ( 4 {a}_{1} {a}_{2} - {a}_{4}^{2} ) - \\ ( 2 {a}_{1} {a}_{6} - {a}_{4} {a}_{5} ) ( 2 {a}_{1} {a}_{8} - {a}_{4} {a}_{7} )\end{matrix}}{( 4 {a}_{1} {a}_{3} - {a}_{5}^{2} ) ( 4 {a}_{1} {a}_{2} - {a}_{4}^{2} ) - 2 {( {a}_{1} {a}_{6} - {a}_{4} {a}_{5} )}^{2}} & ( 4 )\end{matrix}$$

Accordingly, to calculate the offset of the center caused by hard iron interference, ellipsoid parameters are obtained. Since there are nine ellipsoid parameters, nine magnetic field measurements are fitted into equation 1 to calculate the nine ellipsoid parameters to establish a matrix equation as follow:

$$\underbrace{[ \begin{matrix}{x}_{1}^{2} & {y}_{1}^{2} & {z}_{1}^{2} & {x}_{1} {y}_{1} & {x}_{1} {z}_{1} & {y}_{1} {z}_{1} & {x}_{1} & {y}_{1} & {z}_{1} \\ {x}_{2}^{2} & {y}_{2}^{2} & {z}_{2}^{2} & {x}_{2} {y}_{2} & {x}_{2 } {z}_{2} & {y}_{2} {z}_{2} & {x}_{2} & {y}_{2} & {z}_{2} \\ {x}_{3}^{2} & {y}_{3}^{2} & {z}_{3}^{2} & {x}_{3} {y}_{3} & {x}_{3} {z}_{3} & {y}_{3} {z}_{3} & {x}_{3} & {y}_{3} & {z}_{3} \\ {x}_{4}^{2} & {y}_{4}^{2} & {z}_{4}^{2} & {x}_{4} {y}_{4} & {x}_{4} {z}_{4} & {y}_{4} {z}_{4} & {x}_{4} & {y}_{4} & {z}_{4} \\ {x}_{5}^{2} & {y}_{5}^{2} & {z}_{5}^{2} & {x}_{5} {y}_{5} & {x}_{5} {z}_{5} & {y}_{5} {z}_{5} & {x}_{5} & {y}_{5} & {z}_{5} \\ {x}_{6}^{2} & {y}_{6}^{2} & {z}_{6}^{2} & {x}_{6} {y}_{6} & {x}_{6} {z}_{6} & {y}_{6} {z}_{6} & {x}_{6} & {y}_{6} & {z}_{6} \\ {x}_{7}^{2} & {y}_{7}^{2} & {z}_{7}^{2} & {x}_{7} {y}_{7} & {x}_{7} {z}_{7} & {x}_{7} {z}_{7} & {x}_{7} & {y}_{7} & {z}_{7} \\ {x}_{8}^{2} & {y}_{8}^{2} & {z}_{8}^{2} & {x}_{8} {y}_{8} & {x}_{8} {z}_{8} & {x}_{8} {z}_{8} & {x}_{8} & {y}_{8} & {z}_{8} \\ {x}_{9}^{2} & {y}_{9}^{2} & {z}_{9}^{2} & {x}_{9} {y}_{9} & {x}_{9} {z}_{9} & {y}_{9} {z}_{9} & {x}_{9} & {y}_{9} & {z}_{9}\end{matrix} ]}_{B} \underbrace{[ \begin{matrix}{a}_{1} \\ {a}_{2} \\ {a}_{3} \\ {a}_{4} \\ {a}_{5} \\ {a}_{6} \\ {a}_{7} \\ {a}_{8} \\ {a}_{9}\end{matrix} ]}_{A} = \underbrace{[ \begin{matrix}1 \\ 1 \\ 1 \\ 1 \\ 1 \\ 1 \\ 1 \\ 1 \\ 1\end{matrix} ]}_{C} \qquad ( 5 )$$

Equation 5 may be expressed as B·A=C, wherein the matrix B has to be full rank so that equation 5 has a unique solution. Therefore, to achieve a full rank of matrix B, nine different magnetic field measurements are chosen from the plurality of measurements obtained at block 502.

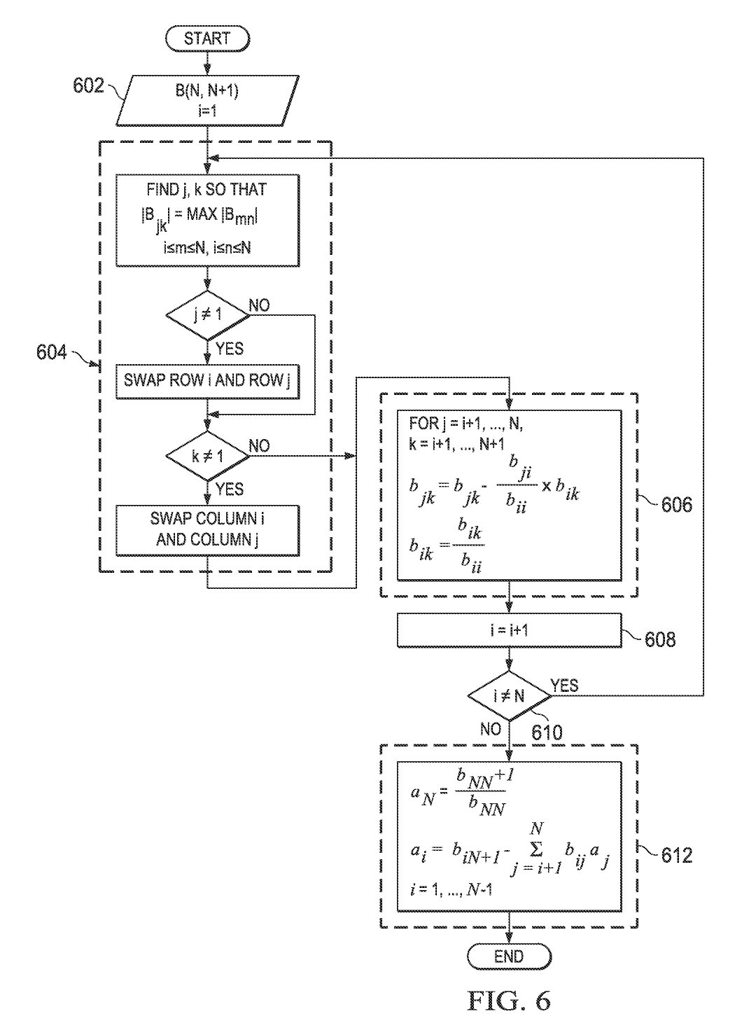

A plurality of methods may be adopted to solve equation 5. In one embodiment, the Gaussian principle elimination method may be used to solve equation 5 with a flowchart illustrated in FIG. 6.

At block 602, an augmented matrix may be established as B(N, N+1)=[B|C] wherein N=9 for example, and i may start as 1. At block 604, the matrix may be traversed and a maximum value bⱼₖ among bₘₙ may be located, wherein i≦m≦N, i≦n≦N. If j does not equal i, the jₜₕ row is swapped with the iₜₕ row; if k does not equal i, the kₜₕ column is swapped with the iₜₕ column, so that bⱼₖ may be moved to the position of bᵢᵢ.

At block 606, operations are taken to eliminate the values at position bᵢⱼ using the equations as follows:

$${b}_{jk} = {b}_{jk} - \frac{{b}_{ji}}{{b}_{ii}} \cdot {b}_{ik} \\ {b}_{ik} = \frac{{b}_{ik}}{{b}_{ii}} \qquad ( 6 )$$

wherein j=i+1, . . . , N, k=i+1, . . . , N+1. At block 608, i may be incremented by 1. At block 610, the operational flow may be directed back to step 604 if i does not equal N.

Therefore, when i reaches N, the N largest values may be positioned on the diagonal of matrix B known as the principles, and the matrix B may be converted into a triangular matrix with the values positioned left to the diagonal eliminated to 0.

At block 612, the ellipsoid parameters are calculated using the equations as follow:

$${a}_{N} = \frac{{b}_{NN + 1}}{{b}_{NN}} \\ {a}_{i} = {b}_{iN + 1} - {\sum }_{j = i + 1}^{N} {b}_{ij} {a}_{j} \qquad ( 7 )$$

wherein i=1, . . . , N−1. The ellipsoid parameter may be obtained in an order of a_{N} to a₁.

After obtaining the ellipsoid parameters, at block 506, the offset of the center of the ellipsoid model is calculated based on the coordinate (x₀, y₀, z₀). At block 508, the magnetic sensor is calibrated based on the offset obtained at block 506.

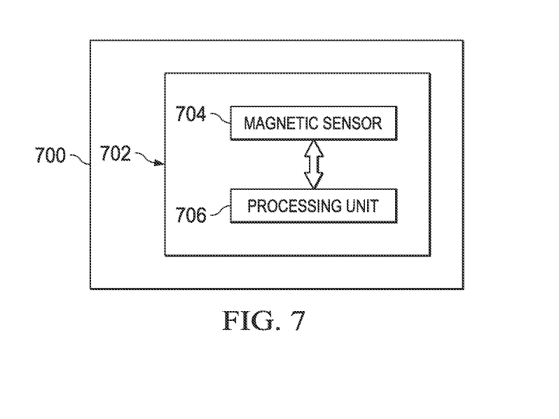

FIG. 7 depicts an exemplary electronic device 700 configured to perform the methods described above. The electronic device may be an electronic compass, a mobile device, a gaming device or an industrial device and so forth which contains a magnetic sensor to be calibrated.

In one embodiment, electronic device 700 comprises a magnetic sensor 704 configured to obtain a plurality of magnetic measurements. In one embodiment, magnetic sensor 704 may be located in an electronic compass 702. Electronic device 700 further comprises a processing unit 706 configured to process the magnetic measurements received from magnetic sensor 704 according to the methods described above. In one embodiment, processing unit 706 may be part of magnetic sensor 704, or electronic compass 702, or may be a shared resource in electronic device 700. In yet another embodiment, processing unit 706 may even be a remote module outside electronic device 700, such as a workstation, a personal computer or a server.

It will be readily understood by those skilled in the art that materials and methods may be varied while remaining within the scope of the present invention. It is also appreciated that the present invention provides many applicable inventive concepts other than the specific contexts used to illustrate embodiments. Accordingly, the appended claims are intended to include within their scope such processes, machines, manufacturing, compositions of matter, means, methods, or steps.

What is claimed is:

1. A method for calibrating a magnetic sensor, comprising:
acquiring a plurality of magnetic field measurements from said magnetic sensor;
fitting at least part of the plurality of magnetic field measurements to an ellipsoid model to obtain a coordinate of a center of the ellipsoid model;
determining a calibration offset according to the coordinate of the center of the ellipsoid model; and
calibrating the magnetic sensor using the calibration offset.

2. The method of claim 1, wherein said step of fitting comprises:
determining an expression of the ellipsoid model containing a plurality of ellipsoid parameters;
substituting at least part of the plurality of magnetic field measurements into the expression of the ellipsoid model to obtain an equation expressed in way of a matrix of the magnetic field measurements and a matrix of the plurality of ellipsoid parameters;
solving the equation using Gaussian principle elimination to obtain the plurality of ellipsoid parameters; and
determining the coordinate of the center of the ellipsoid model using the plurality of ellipsoid parameters.

3. The method of claim 2, wherein said step of solving comprises:
traversing the matrix of the magnetic field measurements to determine principles thereof;
converting the matrix of the magnetic field measurements into a triangular matrix based on the principles obtained; and
solving the equation based on the triangular matrix to obtain the ellipsoid parameters.

4. The method of claim 2, wherein the expression of the ellipsoid model is defined by:
a₁x²+a₂y²+a₃z²+a₄xy+a₅xz+a₆yz+a₇x+a₈y+a₉z=1
wherein (x, y, z) represents a point located on the ellipsoid model, and aₗ-a₉ represent the ellipsoid parameters, and the coordinate of the center of the ellipsoid model is defined by (x₀, y₀, z₀), wherein x₀, y₀ and z₀ are expressed as follows:
$${x}_{0} = - \frac{{a}_{4}}{2 {a}_{1}} {y}_{0} - \frac{{a}_{5}}{2 {a}_{1}} {z}_{0} - \frac{{a}_{7}}{2 {a}_{1}}$$
$${y}_{0} = - \frac{2 {a}_{1} {a}_{6} - {a}_{4} {a}_{5}}{4 {a}_{1} {a}_{2} - {a}_{4}^{2}} {z}_{0} - \frac{2 {a}_{1} {a}_{8} - {a}_{4} {a}_{7}}{4 {a}_{1} {a}_{2} - {a}_{4}^{2}}$$
$${z}_{0} = - \frac{\begin{matrix}( 2 {a}_{1} {a}_{9} - {a}_{7} {a}_{5} ) ( 4 {a}_{1} {a}_{2} - {a}_{4}^{2} ) - \\ ( 2 {a}_{1} {a}_{6} - {a}_{4} {a}_{5} ) ( 2 {a}_{1} {a}_{8} - {a}_{4} {a}_{7} )\end{matrix}}{( 4 {a}_{1} {a}_{3} - {a}_{5}^{2} ) ( 4 {a}_{1} {a}_{2} - {a}_{4}^{2} ) - 2 {( {a}_{1} {a}_{6} - {a}_{4} {a}_{5} )}^{2}}$$

5. The method of claim 1, wherein the plurality of magnetic field measurements comprise at least nine different magnetic field measurements.

6. The method of claim 1, wherein each of the plurality of magnetic field measurements is measured along three orthogonal axes.

7. The method of claim 6, wherein the calibration offset is equal to a vector from an origin of the three orthogonal axes to the center of the ellipsoid model.

8. The method of claim 1, wherein said step of calibrating comprises subtracting the calibration offset from the magnetic field measurements.

9. A magnetic sensor, comprising:
an acquiring device configured to acquire a plurality of magnetic field measurements;
a control device configured to fit at least part of the plurality of magnetic field measurements to an ellipsoid model to obtain a coordinate of a center of the ellipsoid model, and to determine a calibration offset according to the coordinate of the center of the ellipsoid model; and
a calibration device, configured to calibrate the magnetic sensor using the calibration offset.

10. The magnetic sensor of claim 9, wherein said control device is configured to fit at least part of the plurality of magnetic field measurements to an ellipsoid model to obtain a coordinate of a center of the ellipsoid model, and comprises elements configured to:
determine an expression of the ellipsoid model containing a plurality of ellipsoid parameters;
substitute at least part of the plurality of magnetic field measurements into the expression of the ellipsoid model to obtain an equation expressed in way of a matrix of the magnetic field measurements and a matrix of the plurality of ellipsoid parameters;
solve the equation using Gaussian principle elimination to obtain the plurality of ellipsoid parameters; and
determine the coordinate of the center of the ellipsoid model using the plurality of ellipsoid parameters.

11. The magnetic sensor of claim 10, wherein the element in said control device configured to solve the equation comprises sub-elements configured to:
traverse the matrix of the magnetic field measurements to determine principles thereof;
convert the matrix of the magnetic field measurements into a triangular matrix based on the principles obtained; and
solve the equation based on the triangular matrix to obtain the ellipsoid parameters.

12. The magnetic sensor of claim 10, wherein the expression of the ellipsoid model is defined by:
a₁x²+a₂y²+a₃z²+a₄xy+a₅xz+a₆yz+a₇x+a₈y+a₉z=1
wherein (x, y, z) represents a point located on the ellipsoid model, and a₁-a₉ represent the ellipsoid parameters, and the coordinate of the center of the ellipsoid model is defined by (x₀, y₀, z₀), wherein x₀, y₀ and z₀ are expressed as follows:
$${x}_{0} = - \frac{{a}_{4}}{2 {a}_{1}} {y}_{0} - \frac{{a}_{5}}{2 {a}_{1}} {z}_{0} - \frac{{a}_{7}}{2 {a}_{1}}$$
$${y}_{0} = - \frac{2 {a}_{1} {a}_{6} - {a}_{4} {a}_{5}}{4 {a}_{1} {a}_{2} - {a}_{4}^{2}} {z}_{0} - \frac{2 {a}_{1} {a}_{8} - {a}_{4} {a}_{7}}{4 {a}_{1} {a}_{2} - {a}_{4}^{2}}$$
$${z}_{0} = - \frac{\begin{matrix}( 2 {a}_{1} {a}_{9} - {a}_{7} {a}_{5} ) ( 4 {a}_{1} {a}_{2} - {a}_{4}^{2} ) - \\ ( 2 {a}_{1} {a}_{6} - {a}_{4} {a}_{5} ) ( 2 {a}_{1} {a}_{8} - {a}_{4} {a}_{7} )\end{matrix}}{( 4 {a}_{1} {a}_{3} - {a}_{5}^{2} ) ( 4 {a}_{1} {a}_{2} - {a}_{4}^{2} ) - 2 {( {a}_{1} {a}_{6} - {a}_{4} {a}_{5} )}^{2}}$$

13. The magnetic sensor of claim 9, wherein each of the plurality of magnetic field measurements is measured along three orthogonal axes.

14. The magnetic sensor of claim 13, wherein the calibration offset is equal to a vector from an origin of the three orthogonal axes to the center of the ellipsoid model.

15. The magnetic sensor of claim 9, wherein said calibrating device comprises an element configured to subtract the calibration offset from the magnetic field measurements.
